(19) United States
(12) Patent Application Publication
(10) Pub. No.: US 2010/0233598 A1
(43) Pub. Date: Sep. 16, 2010

(54) PATTERN CORRECTING APPARATUS, MASK-PATTERN FORMING METHOD, AND METHOD OF MANUFACTURING SEMICONDUCTOR DEVICE

(76) Inventors: Tetsuaki MATSUNAWA, Kanagawa (JP); Soichi INOUE, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/647,203

(22) Filed: Dec. 24, 2009

(30) Foreign Application Priority Data
Mar. 12, 2009 (JP) 2009-059456

(51) Int. Cl. G03F 7/20; G06K 9/00; G06F 17/50

(52) U.S. Cl. 430/30; 382/144; 716/21

(57) ABSTRACT

A mask-pattern correcting apparatus according to an embodiment of the present invention includes: a pattern-shape variable mask, transmittance or reflectance of which can be changed; a light-receiving element unit that detects an optical image of a mask pattern formed by light irradiated on the pattern-shape variable mask; and a control unit that controls the pattern-shape variable mask to form a mask pattern according to a shape of a design layout and determines a correction amount of the mask pattern such that a difference between an optical image obtained by the light-receiving element unit and the design layout is within a predetermined range.

### CROSS-REFERENCE TO RELATED APPLICATIONS

This application is based upon and claims the benefit of priority from the prior Japanese Patent Application No. 2009-059456, filed on Mar. 12, 2009; the entire contents of which are incorporated herein by reference.

### BACKGROUND OF THE INVENTION

1. Field of the Invention

The present invention relates to a pattern correcting apparatus, a mask-pattern forming method, and a method of manufacturing a semiconductor device using a mask manufactured based on corrected patterns obtained by the pattern correcting apparatus or the mask-pattern forming method.

2. Description of the Related Art

According to microminiaturization of semiconductor devices, deterioration in fidelity and fluctuation in the dimension of patterns due to optical proximity effect have become significant problems in a semiconductor device manufacturing process. To solve such problems, optical proximity effect correction (hereinafter, “OPC”) for deforming patterns of design data is generally carried out to obtain desired patterns when patterns formed on a photomask are transferred onto a wafer.

As the OPC, two methods are generally used. One of the methods is rule-based OPC for determining bias amounts of correction for edges of a mask pattern from attributes of the mask pattern such as the size and the shape of the mask pattern and a proximity state with a mask pattern adjacent to the mask pattern. The other is simulation-based (model-based) OPC for applying light intensity simulation to a mask pattern, extracting a difference between a pattern shape obtained by transferring the mask pattern after deformation and fluctuation in a dimension and a desired shape, and determining bias amounts of correction for edges of the mask pattern from a result of the extraction of the difference (see, for example, Japanese Patent Application Laid-Open No. 2006-292941).

The simulation-based OPC does not need to finely specify the size and the shape of a mask pattern, the proximity state of a mask pattern adjacent to the mask pattern, and the like to determine bias amounts and can realize highly accurate OPC without depending on the shape of the mask pattern. However, in an actual semiconductor integrated circuit, data of a mask pattern has an extremely complicated shape and there are an enormous number of data of the mask pattern. To perform light intensity simulation for the entire mask pattern and perform transfer image prediction for the mask pattern to obtain accuracy for such a pattern having an enormous data amount, enormous calculation load is applied thereto and enormous calculation time is required.

### BRIEF SUMMARY OF THE INVENTION

A mask-pattern correcting apparatus according to an embodiment of the present invention comprises: an illuminating unit; a pattern-shape variable mask formed by arraying a plurality of dot-shaped cells, transmittance or reflectance of which can be changed; an optical-image detecting unit formed by arraying a plurality of dot-shaped optical sensor cells that detect light, the optical-image detecting unit detecting an optical image of a mask pattern formed by the cells of the pattern-shape variable mask; a projection optical system that focuses, on the optical-image detecting unit, light irradiated on the pattern-shape variable mask from the illuminating unit; a mask setting unit that forms the mask pattern with the transmittance or the reflectance of the cells of the pattern-shape variable mask changed according to a shape of a design layout or patterns obtained by processing the design layout; and a correction-amount determining unit that determines, based on a difference between an optical image of the mask patterns obtained by focusing the light, which is irradiated on the mask pattern formed by the mask setting unit, on the optical-image detecting unit via the projection optical system or an image obtained by converting the optical image and the design layout or the patterns obtained by processing the design layout, a correction amount of the mask pattern formed on the pattern-shape variable mask.

A mask-pattern forming method according to an embodiment of the present invention comprises: forming a mask pattern on a pattern-shape variable mask formed by arraying a plurality of dot-shaped cells, transmittance or reflectance of which can be changed, with the transmittance or the reflectance of the cells changed according to a shape of a design layout or a pattern obtained by processing the design layout; irradiating light from an illuminating unit on the pattern-shape variable mask; causing a projection optical system to focus, on an optical-image detecting unit formed by arraying a plurality of dot-shaped optical sensor cells that detect light, the light from the illuminating unit and detecting an optical image of the mask pattern formed on the pattern-shape variable mask; calculating a difference between the optical image of the mask pattern or an image obtained by converting the optical image and the design layout or patterns obtained by processing the design layout and determining whether the difference is within a predetermined range in which the mask pattern does not have to be corrected; determining, when the difference is not within the predetermined range, a correction amount of the mask pattern formed on the pattern-shape variable mask; repeating the formation of the mask pattern to the calculation of the difference until the difference is within the predetermined range; forming, in the formation of the mask pattern performed for a second or subsequent time, the mask pattern on the pattern-shape variable mask according to the design layout or the patterns obtained by processing the design layout and the determined correction amount of the mask pattern; and forming the mask pattern with which the difference is within the predetermined range.

A method of manufacturing a semiconductor device according to an embodiment of the present invention, comprises: forming a mask pattern on a pattern-shape variable mask formed by arraying a plurality of dot-shaped cells, transmittance or reflectance of which can be changed, with the transmittance or the reflectance of the cells changed according to a shape of a design layout or a pattern obtained by processing the design layout; irradiating light from an illuminating unit on the pattern-shape variable mask; causing a projection optical system to focus, on an optical-image detecting unit formed by arraying a plurality of dot-shaped optical sensor cells that detect light, the light from the illuminating unit and detecting an optical image of the mask pattern formed on the pattern-shape variable mask; calculating a difference between the optical image of the mask pattern or an image obtained by converting the optical image and the design layout or patterns obtained by processing the design layout and determining whether the difference is within a predetermined range in which the mask pattern does not have to be corrected; determining, when the difference is not within the predetermined range, a correction amount of the mask pattern formed on the pattern-shape variable mask; repeating the formation of the mask pattern to the calculation of the difference until the difference is within the predetermined range; forming, in the formation of the mask pattern performed for a second or subsequent time, the mask pattern on the pattern-shape variable mask according to the design layout or the patterns obtained by processing the design layout and the determined correction amount of the mask pattern; and manufacturing a semiconductor device using a product mask manufactured based on the mask pattern with which the difference is within the predetermined range.

### BRIEF DESCRIPTION OF THE DRAWINGS

FIG. 1 is a schematic block diagram of the configuration of a mask-pattern correcting apparatus according to a first embodiment of the present invention;

FIG. 2 is a schematic diagram of the configuration of an optical-image acquiring unit including a transmissive pattern-shape variable mask;

FIG. 3 is a schematic diagram of the configuration of an optical-image acquiring unit including a reflective pattern-shape variable mask;

FIG. 4 is a schematic diagram of an example of a pattern-shape variable mask;

FIG. 5 is a schematic diagram of the plane structure of a light-receiving element unit;

FIG. 6 is a flowchart for explaining an example of a processing procedure of a mask-pattern correcting method according to the first embodiment;

FIG. 7 is a diagram of an example of a design layout;

FIG. 8 is a diagram of an example of the pattern-shape variable mask on which a mask pattern is formed; and

FIG. 9 is a graph of an example of signal intensity obtained in a part of the light-receiving element unit.

### DETAILED DESCRIPTION OF THE INVENTION

Exemplary embodiments of the present invention are explained in detail below with reference to the accompanying drawings. The present invention is not limited by the embodiments.

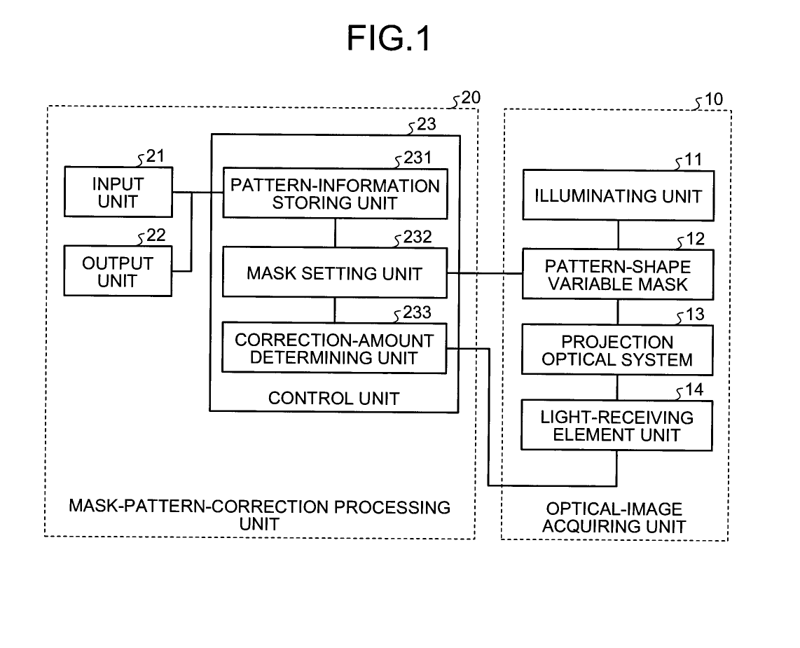

FIG. 1 is a schematic block diagram of the configuration of a mask-pattern correcting apparatus according to a first embodiment of the present invention. The mask-pattern correcting apparatus includes an optical-image acquiring unit 10 that irradiates light on a mask pattern and acquires an optical image of the mask pattern and a mask-pattern-correction processing unit 20 that inputs the shape of the mask pattern to the optical-image acquiring unit 10, determines whether the optical image of the mask pattern coincides with a desired shape, for example, a design layout, and determines a correction amount of the mask pattern when the optical image does not coincide with the desired shape.

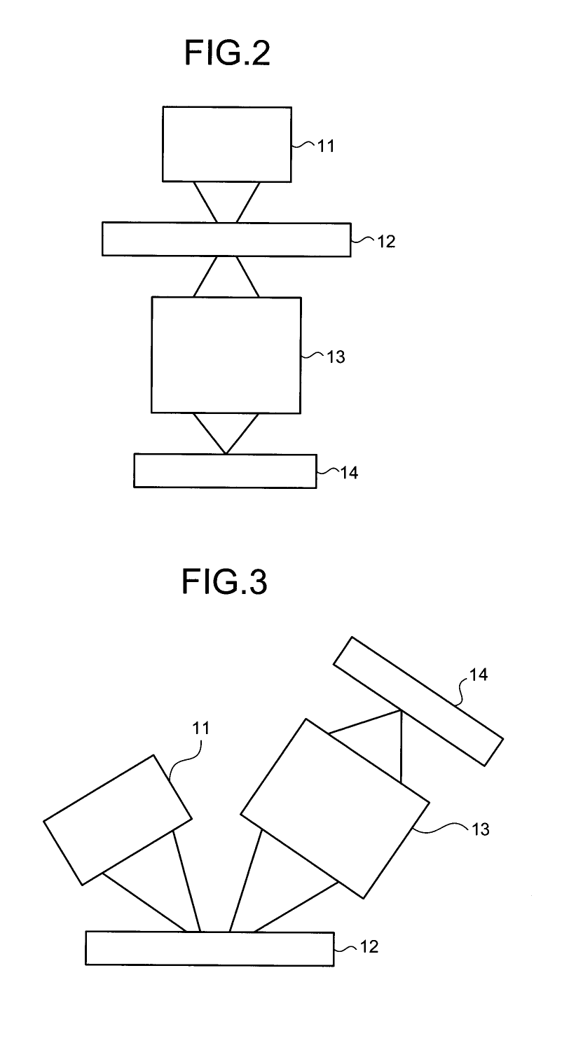

The optical-image acquiring unit 10 includes an illuminating unit 11, a pattern-shape variable mask 12, a projection optical system 13, and a light-receiving element unit 14. FIG. 2 is a schematic diagram of the configuration of an optical-image acquiring unit including a transmissive pattern-shape variable mask. FIG. 3 is a schematic diagram of the configuration of an optical-image acquiring unit including a reflective pattern-shape variable mask. The optical-image acquiring unit shown in FIG. 2 causes the pattern-shape variable mask 12 to transmit light and detects, with the light-receiving element unit 14, an image of the light focused by the projection optical system 13. On the other hand, the optical-image acquiring unit shown in FIG. 3 causes the pattern-shape variable mask 12 to reflect light and detects, with the light-receiving element unit 14, an image of the reflected light focused by the projection optical system 13.

The illuminating unit 11 is a light source that emits lights having wavelengths of a visible ray to an ultraviolet ray (including an extreme ultraviolet (EUV) ray). When necessary, the illuminating unit 11 further includes an illumination optical system having an optical element such as a lens arranged to radiate the light from the light source on the pattern-shape variable mask 12. The light source can be a coherent light source or an incoherent light source and can be a single-color light source or a light source including a plurality of wavelengths. For example, an ArF laser, a KrF laser, an ultra-high pressure mercury lamp, a laser in a visible light region, white light, or the like can be used.

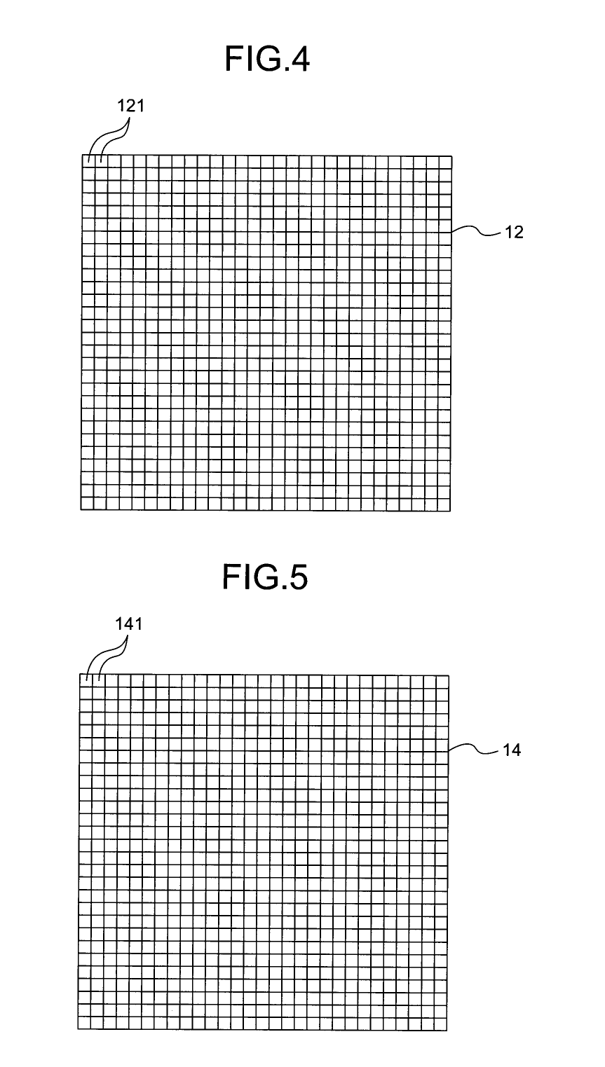

The pattern-shape variable mask 12 is equivalent to a mask pattern (a reticle) of an exposing device and is a mask that can represents a pattern shape input according to an instruction from the mask-pattern-correction processing unit 20. FIG. 4 is a schematic diagram of an example of the pattern-shape variable mask. As shown in the figure, the pattern-shape variable mask 12 includes a dot array in which cells 121, transmittance (0% to 100%) or reflectance (0% to 100%) of which is controlled, are arranged in a matrix shape. This mask-pattern correcting apparatus is an apparatus for correcting the influence by the optical proximity effect and only has to be capable of reproducing the optical proximity effect. Therefore, a relation between wavelength used by the illuminating unit 11 and the size of a mask only has to be the same as a relation between exposure wavelength and the size of a mask in an actual semiconductor device manufacturing process. In other words, a mask having size same as the wavelength of light used in the actual semiconductor device manufacturing process does not have to be used.

As the pattern-shape variable mask 12 used in the transmissive optical-image acquiring unit 10 shown in FIG. 2, a pattern-shape variable mask in which liquid cells, light transmittance (e.g., transmissive or non-transmissive) of which can be controlled, are arranged in a matrix shape. Specifically, in a normal mask pattern, a light blocking section and a light transmitting section are formed by patterning a transparent substrate with a light blocking film. However, in the pattern-shape variable mask 12 including the liquid crystal cells, liquid crystal cells set not to transmit light form a light blocking section and liquid crystal cells set to transmit light form a light transmitting section. An image is formed on the light-receiving element unit 14 by light transmitted through such a pattern-shape variable mask 12.

As the pattern-shape variable mask 12 used in the reflective optical-image acquiring unit 10 shown in FIG. 3, for example, a display device including liquid crystal cells, light reflectance (e.g., absorption and reflection) of which can be controlled, can be used. A micro-electromechanical system (MEMS) device such as a deformable micro-mirror device or digital micro-mirror device (DMD) can also be used in which a plurality of micro mirrors, inclination angles of reflection surfaces of which can be changed, are arranged in a matrix shape to control angles of the respective mirrors and switch presence or absence of reflection. An image is formed on the light-receiving element unit 14 by light reflected on such a pattern-shape variable mask 12.

As explained above, the pattern-shape variable mask 12 includes the liquid cells or the like. Therefore, the pattern-shape variable mask 12 can instantaneously change a pattern shape to an arbitrary shape according to a control signal. As a result, unlike a mask actually used in the exposing device, it is unnecessary to form patterns on a mask substrate using a rendering technology and an etching technology. Therefore, it is possible to substantially reduce time required for changing (correcting) a mask pattern.

The projection optical system 13 includes an optical element such as a lens (when the transmissive pattern-shape variable mask 12 is used) or a mirror (when the reflective pattern-shape variable mask 12 is used) arranged such that light transmitted through the pattern-shape variable mask 12 focuses an image on the light-receiving element unit 14.

The light-receiving element unit 14 is an element unit in which optical sensor cells including photoelectric conversion elements that convert light of a photodiode or the like into an electric signal are arranged in a matrix shape. As the light-receiving element unit 14, a charge-coupled device (CCD) image sensor, a complementary metal-oxide semiconductor (CMOS) image sensor, or the like can be used. FIG. 5 is a schematic diagram of the plane structure of the light-receiving element unit. Like the pattern-shape variable mask 12, the light-receiving element unit 14 has structure in which optical sensor cells 141 are arranged in a matrix shape. Signals detected by the optical sensor cells 141 of the light-receiving element unit 14 are output to the mask-pattern-correction processing unit 20. The light-receiving element unit 14 corresponds to an optical-image detecting unit.

The mask-pattern-correction processing unit 20 includes an input unit 20, an output unit 22, and a control unit 23. The input unit 21 has a function of inputting a design layout or patterns obtained by processing the design layout. The patterns obtained by processing the design layout are, for example, patterns obtained by converting the design layout into EB rendering data, patterns obtained by applying correction (e.g., optical proximity effect correction) to the design layout, or patterns that should be formed on a resist film in actual semiconductor manufacturing (patterns as lithography targets). The design layout has a shape identical with a shape of patterns actually desired to be formed. When a difference between a design layout set by the control unit 23 and an optical image of the pattern-shape variable mask 12 formed on the light-receiving element unit 14 is within tolerance, the output unit 22 outputs corrected design layout data or data obtained by processing the design layout.

The control unit 23 includes a pattern-information storing unit 231, a mask setting unit 232, and a correction-amount determining unit 233. The control unit 23 is electrically connected to the pattern-shape variable mask 12 and the light-receiving element unit 14.

The pattern-information storing unit 231 stores the design layout or the pattern obtained by processing the design layout input from the input unit 21 and a correction amount of the design layout determined by the correction-amount determining unit 233. In the design layout, areas are divided in a dot shape according to the cells 121 of the pattern-shape variable mask 12. Information concerning presence or absence of patterns is recorded for the respective dot-shaped areas.

The mask setting unit 232 sets the design layout, which is stored in the pattern-information storing unit 231, in the pattern-shape variable mask 12 with, if a pattern correction amount is included in the design layout, the pattern correction amount reflected on the pattern-shape variable mask 12. This setting is the same as, for example, a mechanism for causing a liquid crystal display device to display an image. For example, in the case of the transmissive pattern-shape variable mask 12 in which liquid crystal cells are arranged in a matrix shape, the mask setting unit 232 sets cells present in positions corresponding to a masked section of input patterns as non-transmissive and sets cells present in positions corresponding to an unmasked section of the design layout as transmissive. Consequently, the mask-shape variable mask 12 changes to a mask having patterns corresponding to the design layout.

The correction-amount determining unit 233 generates an optical image of a mask pattern using signals acquired by the optical sensor cells 141 of the light-receiving element unit 14 as a result of light irradiation on the pattern-shape variable mask 12 set by the mask setting unit 232 from the illuminating unit 11. The correction-amount determining unit 233 compares the optical image and the design layout and determines, based on a difference between the optical image and the design layout, a correction amount of the patterns set on the pattern-shape variable mask 12 to, for example, reduce the difference to be equal to or smaller than the tolerance. Specifically, the correction-amount determining unit 233 determines the correction amount such that, concerning measurement points set in advance, an edge position difference amount as a difference between edge positions of a mask pattern optical image and edge positions of the design layout is within an allowable edge position shift amount set in advance. For example, the correction-amount determining unit 233 can set a calculated difference amount as a correction amount with the magnifications of the patterns in the mask 12 and the patterns in the light-receiving element unit 14 reflected on the correction amount. Alternatively, the correction-amount determining unit 233 can apply predetermined processing to the difference amount to calculate a correction amount. The determination of a correction amount can be appropriately changed according to the configuration of a mask-pattern correcting apparatus in use. The determined correction amount is stored in the pattern-information storing unit 231 in association with a position in the design layout.

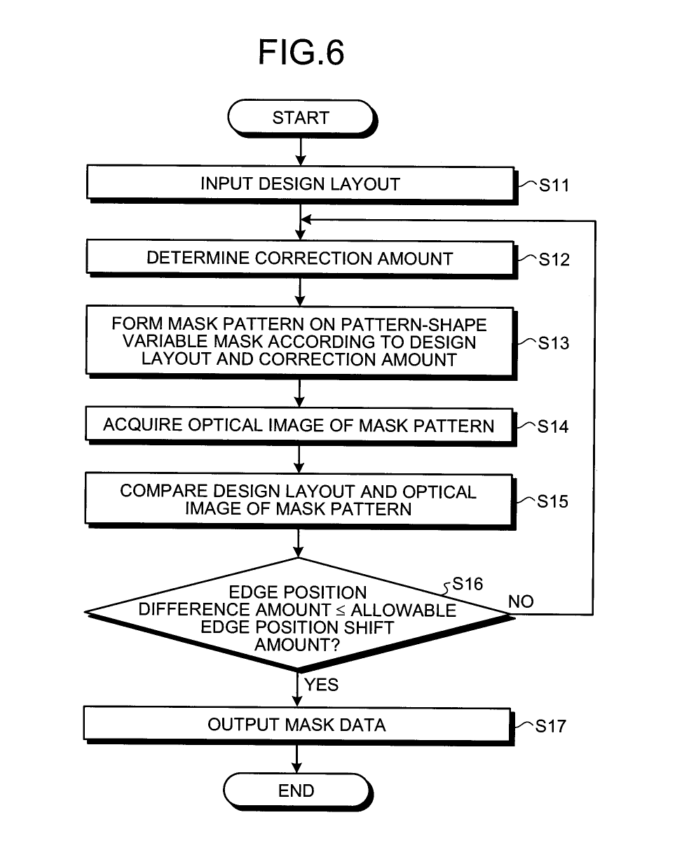

FIG. 6 is a flowchart for explaining an example of a processing procedure of a mask-pattern correcting method in the mask-pattern correcting apparatus according to the first embodiment.

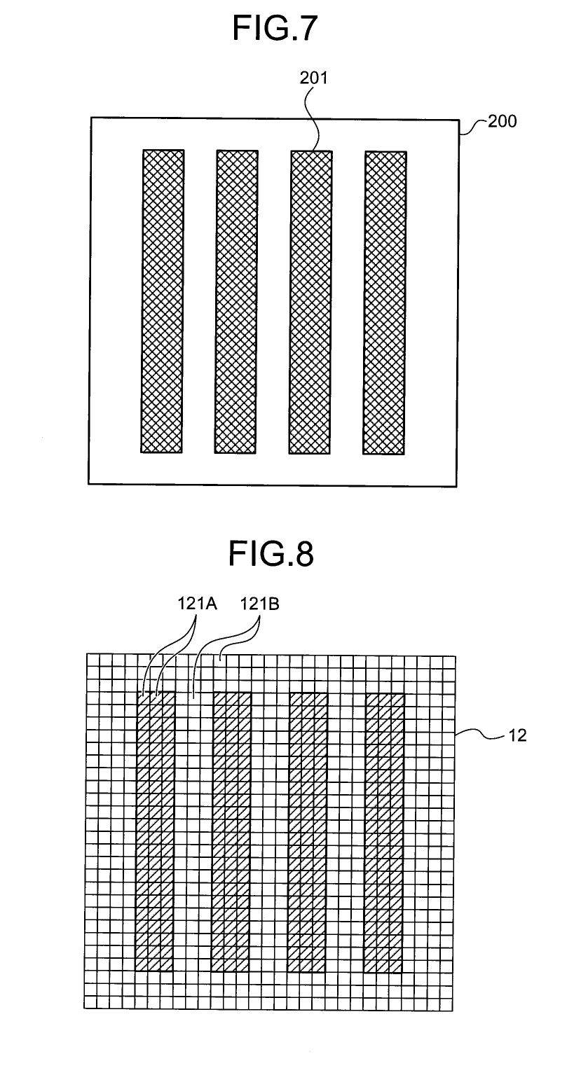

First, a user inputs a design layout via the input unit 21 (step S11). The design layout is stored in the pattern-information storing unit 231. FIG. 7 is a diagram of an example of the design layout. In a design layout 200 shown in the figure, as an example, four line-shaped patterns 201 are formed in parallel. In the figure, the patterns 201 are hatched. Thereafter, the correction-amount determining unit 233 determines a correction amount (step S12). When only the design layout is input, the correction-amount determining unit 233 sets the correction amount to “0” and stores the design layout in the pattern-information storing unit 231.

Subsequently, the mask setting unit 232 forms patterns on the pattern-shape variable mask 12 according to the design layout stored in the pattern-information storing unit 231 and the determined correction amount (step S13). Actually, because the correction amount is “0”, the mask setting unit 232 forms patterns according to the design layout stored in the pattern-information storing unit 231.

FIG. 8 is a diagram of an example of the pattern-shape variable mask on which a mask pattern is formed. In the figure, the design layout shown in FIG. 7 is set on the pattern-shape variable mask 12. For example, in the case of the transmissive pattern-shape variable mask 12 including liquid crystal cells, the design layout stored in the pattern-information storing unit 231 is divided into dot-shaped areas. Therefore, the mask setting unit 232 controls the transmittance of the liquid crystal cells 121 according to the design layout and the correction amount to set, if a light blocking section is present in the dot-shaped areas, liquid crystal cells 121A in positions corresponding to the dot-shaped areas as non-transmissive and set, if a light blocking section is not present in the dot-shaped areas, liquid crystal cells in positions corresponding to the dot-shaped areas as transmissive.

Similarly, in the case of the reflective pattern-shape variable mask 12 including liquid crystal cells, the mask setting unit 232 changes the absorptance (black or not) in the positions of the liquid crystal cells according to the design layout and the correction amount. In the case of the reflective pattern-shape variable mask 12 including a MEMS device, the mask setting unit 232 changes the reflectance of mirrors in the cell positions according to the design layout and the correction amount.

Thereafter, the illuminating unit 11 irradiates light on the pattern-shape variable mask 12. The light-receiving element unit 14 obtains an optical image of the mask pattern formed on the pattern-shape variable mask 12 (step S14). It is assumed that electric signals corresponding to the intensity of the received light are output from the sensor cells 141 in the positions of the light-receiving unit 14.

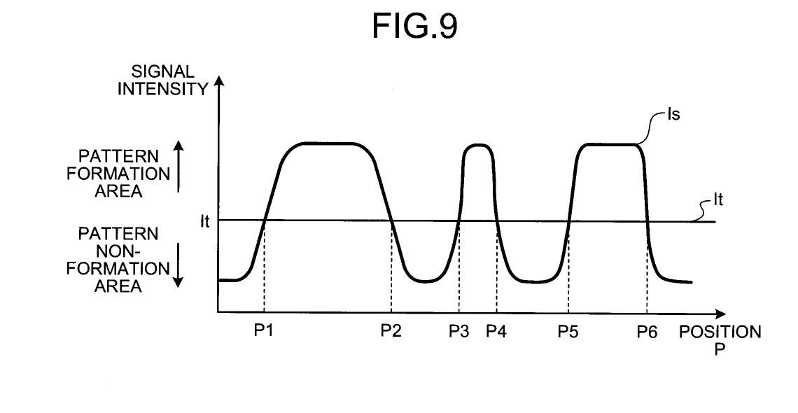

FIG. 9 is a graph of an example of signal intensity obtained in a part of the light-receiving element unit. In the figure, the abscissa indicates positions P along a straight light on the light-receiving element unit 14 and the ordinate indicates signal intensities (light intensities) in the positions P. In the figure, as indicated by a curved line Is, it is assumed that signal intensities are detected in the respective positions (sensor cells). It is assumed that, when the signal intensity Is is equal to or larger than a pattern determination threshold It, the position is in a pattern formation area. Specifically, when a straight line It parallel to the abscissa is drawn on FIG. 7, the pattern formation area can be determined according to a magnitude relation between the signal intensity Is and the pattern determination threshold It. This is an example in which resist as a light irradiation target used in an actual semiconductor device manufacturing process is positive resist. A resist section having the signal intensity Is equal to or larger than the pattern determination threshold It is removed by a developing process and patterns are formed. On the other hand, as another example, when the resist is negative resist, a resist section having the signal intensity Is equal to or smaller than the pattern determination threshold It is removed by the developing process and patterns are formed.

As a result, in FIG. 7, areas (the positions P on the abscissa) where Is≧It are pattern formation areas and areas (the positions P on the abscissa) where Is<It are pattern non-formation areas. In this way, the correction-amount determining unit 233 acquires an optical image in which the pattern formation areas and the pattern non-formation areas are divided.

Subsequently, the correction-amount determining unit 233 compares the design layout stored in the pattern-information storing unit 231 and a light intensity distribution of the acquired optical image (step S15). The correction-amount determining unit 233 determines whether an edge position difference amount as a difference between edge positions of patterns of the design layout and edge positions of the pattern formation areas of the optical image is within the allowable edge position shift amount (step S16). This determination can be performed in all sections. However, it is also possible to set a plurality of measurement points, where measurement is performed, on the design layout and perform the determination at the measurement points.

When it is assumed that the signal intensities at the measurement points are shown in FIG. 9, in FIG. 9, the positions P1 to P6 as intersections of the signal intensity Is and the pattern determination threshold It are extracted as edge positions of the pattern formation areas. It is assumed that edge positions at measurement points corresponding to FIG. 9 of the design layout are E1 to E6 (not shown in the figure). The correction-amount determining unit 233 calculates a difference Pi−Ei=EPi (i=1 to 6) between edge positions Pi of the pattern formation areas of the optical image at the measurement points and edge positions Ei of the patterns of the design layout. The correction-amount determining unit 233 determines whether the difference EPi between the edge positions is within an allowable edge position shift amount EP0 set in advance.

When the edge position difference amount EPi is larger than the allowable edge position shift amount EP0 (“No” at step S16), the procedure returns to the correction amount calculation processing at step S12. In the correction amount calculation processing, the correction-amount determining unit 233 determines, based on the acquired edge position difference amount EPi, a correction amount for the shape of the mask pattern on the pattern-shape variable mask 12 necessary for reducing the edge position difference amount EPi to be equal to or smaller than the allowable edge position shift amount EP0. The correction-amount determining unit 233 stores the correction amount in the pattern-information storing unit 231 together with correction positions of the mask pattern.

Thereafter, at step S13, the mask setting unit 232 sets a mask pattern on the pattern-shape variable mask 12 according to the design layout stored in the pattern-information storing unit 231 and the correction amount determined at step S12. For example, after forming a mask pattern on the pattern-shape variable mask 12 according to the design layout first, the mask setting unit 232 performs processing for thickening or thinning patterns in respective positions of the formed mask pattern.

The mask setting unit 232 repeats the processing at steps S12 to S16 until the edge position difference amount EPi is reduced to be equal to or smaller than the allowable edge position shift amount EP0 at all the measurement points at step S16.

When the edge position difference amount EPi is equal to or smaller than the allowable edge position shift amount EP0 at all the measurement points (“Yes” at step S16), this indicates that the optical image of the mask pattern has a shape substantially the same as the design layout. Therefore, the output unit 22 outputs, as mask data, a design layout obtained by reflecting the correction amount to that point on the design layout (step S17). Consequently, the method of correcting a mask pattern ends and pattern data with the optical proximity effect corrected can be obtained.

In the processing for determining a correction amount at step S12, an optical image in a shot can be instantaneously calculated from the light-receiving element unit 14. Therefore, the correction-amount determining unit 233 can determine a correction amount taking into account global loading effect. For example, the correction-amount determining unit 233 adds a bias amount based on an error used for global alignment of a mask and a wafer for suppressing pattern fluctuation on the wafer due to a difference in a shot position to an optical image distribution acquired from the light-receiving element unit 14. Then, the correction-amount determining unit 233 can determine a correction amount taking into account pattern fluctuation due to a difference in a shot position.

According to the first embodiment, an optical image of a mask pattern can be instantaneously obtained by using an optical device. Therefore, it is possible to directly obtain an optical image without performing a prediction calculation for the optical image used in the optical proximity effect correction technology in the past. It is possible to obtain a highly accurate mask pattern with the optical proximity effect corrected based on a result of the optical image. As a result, there is an effect that it is possible to substantially reduce time required for the optical proximity effect correction processing compared with that in the past.

The pattern-shape variable mask 12 in which liquid crystal cells or the like are arranged in a matrix shape is used as a mask. Therefore, it is possible to easily and instantaneously apply the optical proximity effect correction, which is performed when an optical image of a mask pattern obtained by the light-receiving element unit 14 is different from a desired design layout, to the mask pattern. As a result, there is an effect that it is possible to reduce time required for recreation of the mask pattern.

Further, an optical image in a shot can be instantaneously obtained from the light-receiving element unit 14. Therefore, there is an effect that it is possible to eliminate the influence of the global loading effect that prevents an image from being uniformly formed depending on a place (a position) on a wafer.

In a second embodiment of the present invention, a filter can be inserted in a pupil position of the illuminating unit 11 (the light source) of the mask-pattern correcting apparatus according to the first embodiment. By inserting the filter in this way, a shape of a light source irradiated on the pattern-shape variable mask 12 can be arbitrarily changed. A light source in an exposing device employing the modified illumination method can be reproduced. As the filter, for example, a diffractive optical element having a plurality of light transmittances can be used. Illumination light such as zonal illumination, dipole illumination, and quadrupole illumination can be realized. A mask-pattern correcting method employing such modified illumination is the same as that explained in the first embodiment. Therefore, explanation of the method is omitted.

According to the second embodiment, the light source in the exposing device employing the modified illumination method, with which a high-resolution optical image can be obtained, can be reproduced as the illuminating unit 11. Therefore, concerning a high-resolution optical image obtained by the light-receiving element unit 14, it is possible to directly obtain an optical image without performing the prediction calculation for the optical image used in the optical proximity effect correction technology in the past and obtain a corrected mask pattern with the optical proximity effect corrected based on a result of the optical image. As a result, there is an effect that it is possible to substantially reduce time required for the optical proximity effect correction processing compared with that in the past and improve accuracy of correction.

In a third embodiment of the present invention, a Gaussian filter or the like in which light amplitude transmittances are distributed according to the Gaussian distribution can be inserted in a pupil position of the projection optical system 13 of the mask-pattern correcting apparatus. By inserting such a filter, an optical image obtained from the light-receiving element unit 14 is formed in a shape with diffusion of acid of resist taken into account. Therefore, it is possible to represent diffusion behavior in a baking process of acid generated in exposed resist in actual manufacturing of a semiconductor device. It is possible to represent the shape of the resist dissolved according to a density distribution of the acid in the following developing process.

As the filter arranged in the pupil position of the projection optical system 13, for example, a diffractive optical element that can arbitrarily set a transmittance distribution on a pupil surface or a filter that can give an arbitrary phase difference can be adopted. By inserting such a filter, a pupil transmittance distribution in an exposing device and aberration of a projection lens system in the exposing device can be reproduced. An optical image obtained by the light-receiving element unit 14 is equivalent to a contour image on the resist in the exposing device. A mask-pattern correcting method in the mask-pattern correcting apparatus including the projection optical system 13 including such a filter is the same as that in the first embodiment. Therefore, explanation of the method is omitted.

According to the third embodiment, by inserting the filter in the pupil position of the projection optical system 13, the light-receiving element unit 14 can obtain an optical image having a shape with diffusion of acid of resist taken into account and an optical image equivalent to a contour image on the resist. Therefore, there is an effect that it is possible to further improve correction accuracy for the optical proximity effect according to such a result of the optical images.

In a fourth embodiment of the present invention, in the light-receiving element unit 14 of the mask-pattern correcting apparatus, the light-receiving element unit 14 can be set movable in an optical axis direction. By changing a position in the optical axis direction of the light-receiving element unit 14 in this way, a focal position can be changed. The light-receiving element unit 14 can obtain an optical image of the pattern-shape variable mask 12 on an arbitrary focal surface.

A mask-pattern correcting method in the mask-pattern correcting apparatus having such a light-receiving element unit 14 movable in the optical axis direction is the same as that in the first embodiment. Therefore, explanation of the method is omitted. When a correction amount is determined based on an edge position of the optical image obtained in the fourth embodiment, a correction amount with a latent image taken into account is obtained as in a state in which a resist pattern is formed on a wafer by using the exposing device.

According to the fourth embodiment, by setting the light-receiving element unit 14 movable in the optical axis direction, a correction amount with a latent image taken into account can be obtained as in the state in which a resist pattern is formed on a wafer using the exposing device. Therefore, there is an effect that it is possible to improve correction accuracy for the optical proximity effect. Further, it is possible to perform correction of the optical proximity effect with even the height of photoresist formed, for example, during actual manufacturing of a semiconductor device taken into account.

In the embodiments explained above, pattern correction is carried out by comparing an obtained optical image and a design layout. However, it is also possible to compare an image obtained by applying some kind of conversion to the obtained optical image and the design layout and perform the pattern correction according to whether a difference between the image and the design layout is equal to or smaller than tolerance.

For example, an image obtained by converting the optical image taking into account fluctuation in patterns in a developing process and an etching process, which are carried out after an exposing process in the actual manufacturing of a semiconductor device, and the design layout can be compared. The fluctuation in the patterns in the developing process and the etching process can be acquired with reference to a relation between an optical image distribution or a pattern arrangement state and a fluctuation amount of patterns acquired in advance. Alternatively, a pattern fluctuation amount can also be acquired from the optical image distribution or the pattern arrangement state by using predetermined development and etching simulation or a predetermined calculation formula. This conversion is carried out by, for example, the correction-amount calculating unit 233 to which the optical image obtained by the light-receiving element unit 14 shown in FIG. 1 is input.

In the embodiments, a product mask is manufactured based on a design layout obtained by performing correction. A semiconductor device (a semiconductor integrated circuit) is manufactured by using the product mask. Specifically, a product mask is manufactured based on design layout data in which all differences between the design layout and optical images of the pattern-shape variable mask 12 formed on the light-receiving element unit 14 are within the tolerance. A workpiece such as a wafer applied with resist is exposed by using the product mask and developed to form a resist pattern on the workpiece. Thereafter, the workpiece is etched by using the resist pattern as a mask. Consequently, actual patterns having a desired shape are formed on the wafer. A semiconductor device is manufactured by repeating such processing. The workpiece is the wafer itself or an insulating film or a conductive material film formed on the wafer.

As explained above, according to the embodiments of the present invention, there is an effect that, in correction processing for patterns used for manufacturing of a semiconductor device, it is possible to perform the correction processing at high speed and high accuracy.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A mask-pattern correcting apparatus comprising:
an illuminating unit;
a pattern-shape variable mask formed by arraying a plurality of dot-shaped cells, transmittance or reflectance of which can be changed;
an optical-image detecting unit formed by arraying a plurality of dot-shaped optical sensor cells that detect light, the optical-image detecting unit detecting an optical image of a mask pattern formed by the cells of the pattern-shape variable mask;
a projection optical system that focuses, on the optical-image detecting unit, light irradiated on the pattern-shape variable mask from the illuminating unit;
a mask setting unit that forms the mask pattern with the transmittance or the reflectance of the cells of the pattern-shape variable mask changed according to a shape of a design layout or patterns obtained by processing the design layout; and
a correction-amount determining unit that determines, based on a difference between an optical image of the mask patterns obtained by focusing the light, which is irradiated on the mask pattern formed by the mask setting unit, on the optical-image detecting unit via the projection optical system or an image obtained by converting the optical image and the design layout or the patterns obtained by processing the design layout, a correction amount of the mask pattern formed on the pattern-shape variable mask.

2. The mask-pattern correcting apparatus according to claim 1, wherein the mask setting unit forms, when a correction amount of the mask pattern is not determined by the correction-amount determining unit, the mask pattern with the transmittance or the reflectance of the cells of the pattern-shape variable mask and the mask pattern changed based on the design layout input with the correction amount set to 0.

3. The mask-pattern correcting apparatus according to claim 1, wherein the mask setting unit applies, with the correction amount of the mask pattern determined by the correction-amount determining unit, correction of the transmittance or the reflectance of the cells of the pattern-shape variable mask to the mask pattern formed on the pattern-shape variable mask to correspond to the design layout or the patterns obtained by processing the design layout to form a new mask pattern.

4. The mask-pattern correcting apparatus according to claim 1, wherein the correction-amount determining unit calculates the difference concerning measurement points set in advance on the design layout and determines a correction amount of the mask pattern.

5. The mask-pattern correcting apparatus according to claim 1, wherein the correction-amount determining unit adds a predetermined bias amount to the optical image of the mask pattern obtained from the optical-image detecting unit or the image obtained by converting the optical image.

6. The mask-pattern correcting apparatus according to claim 1, wherein the illuminating unit is a light source that emits light in a predetermined wavelength range among lights having wavelengths of a visible ray to an ultraviolet ray including EUV light.

7. The mask-pattern correcting apparatus according to claim 1, wherein the pattern-shape variable mask is a display device in which liquid crystal cells, light transmittance or reflectance of which can be controlled, are arranged in a matrix shape.

8. The mask-pattern correcting apparatus according to claim 1, wherein the pattern-shape variable mask is a MEMS device in which a plurality of micro-mirrors, tilt angles of reflection surfaces of which can be changed, are arranged in a matrix shape.

9. The mask-pattern correcting apparatus according to claim 1, wherein the illuminating unit includes a filter in a pupil position.

10. The mask-pattern correcting apparatus according to claim 9, wherein the filter is a diffractive optical element including a plurality of light transmittances.

11. The mask-pattern correcting apparatus according to claim 1, wherein the projection optical system includes a filter in a pupil position.

12. The mask-pattern correcting apparatus according to claim 11, wherein the filter is a Gaussian filter, light amplitude transmittance of which is a Gaussian distribution.

13. The mask-pattern correcting apparatus according to claim 1, wherein the optical-image detecting unit can move in an optical axis direction.

14. A mask-pattern forming method comprising:
forming a mask pattern on a pattern-shape variable mask formed by arraying a plurality of dot-shaped cells, transmittance or reflectance of which can be changed, with the transmittance or the reflectance of the cells changed according to a shape of a design layout or a pattern obtained by processing the design layout;
irradiating light from an illuminating unit on the pattern-shape variable mask;
causing a projection optical system to focus, on an optical-image detecting unit formed by arraying a plurality of dot-shaped optical sensor cells that detect light, the light from the illuminating unit and detecting an optical image of the mask pattern formed on the pattern-shape variable mask;
calculating a difference between the optical image of the mask pattern or an image obtained by converting the optical image and the design layout or patterns obtained by processing the design layout and determining whether the difference is within a predetermined range in which the mask pattern does not have to be corrected;
determining, when the difference is not within the predetermined range, a correction amount of the mask pattern formed on the pattern-shape variable mask;
repeating the formation of the mask pattern to the calculation of the difference until the difference is within the predetermined range;
forming, in the formation of the mask pattern performed for a second or subsequent time, the mask pattern on the pattern-shape variable mask according to the design layout or the patterns obtained by processing the design layout and the determined correction amount of the mask pattern; and
forming the mask pattern with which the difference is within the predetermined range.

15. The mask-pattern forming method according to claim 14, wherein the determining the correction amount includes calculating the difference concerning measurement points set in advance on the design layout and determining a correction amount of the mask pattern.

16. The mask-pattern forming method according to claim 14, wherein the determining the correction amount includes adding a predetermined bias amount to the optical image of the mask pattern or the image obtained by converting the optical image and then calculating the difference.

17. The mask-pattern forming method according to claim 14, wherein the illuminating unit includes a filter in a pupil position.

18. The mask-pattern forming method according to claim 14, wherein the projection optical system includes a filter in a pupil position.

19. The mask-pattern forming method according to claim 14, wherein, in the detecting the optical image, the optical-image detecting unit can be moved in an optical axis direction.

20. A method of manufacturing a semiconductor device, comprising:
forming a mask pattern on a pattern-shape variable mask formed by arraying a plurality of dot-shaped cells, transmittance or reflectance of which can be changed, with the transmittance or the reflectance of the cells changed according to a shape of a design layout or a pattern obtained by processing the design layout;
irradiating light from an illuminating unit on the pattern-shape variable mask;
causing a projection optical system to focus, on an optical-image detecting unit formed by arraying a plurality of dot-shaped optical sensor cells that detect light, the light from the illuminating unit and detecting an optical image of the mask pattern formed on the pattern-shape variable mask;
calculating a difference between the optical image of the mask pattern or an image obtained by converting the optical image and the design layout or patterns obtained by processing the design layout and determining whether the difference is within a predetermined range in which the mask pattern does not have to be corrected;
determining, when the difference is not within the predetermined range, a correction amount of the mask pattern formed on the pattern-shape variable mask;
repeating the formation of the mask pattern to the calculation of the difference until the difference is within the predetermined range;
forming, in the formation of the mask pattern performed for a second or subsequent time, the mask pattern on the pattern-shape variable mask according to the design layout or the patterns obtained by processing the design layout and the determined correction amount of the mask pattern; and
manufacturing a semiconductor device using a product mask manufactured based on the mask pattern with which the difference is within the predetermined range.
